(19) United States
(12) Patent Application Publication
(10) Pub. No.: US 2025/0227851 A1
(43) Pub. Date: Jul. 10, 2025

(54) SUBSTRATE SUPPORT WITH PRINTED HEATER

(71) Applicant: Tokyo Electron Limited, Tokyo (JP)

(72) Inventor: Melvin Verbaas, Austin, TX (US)

(21) Appl. No.: 18/406,451

(22) Filed: Jan. 8, 2024

(51) Int. Cl. H05K 1/18; H05K 1/02; H05K 3/10

(52) U.S. Cl. CPC H05K 1/185; H05K 1/0212; H05K 3/103; H05K 2201/0195; H05K 2201/10212

(57) ABSTRACT

A substrate support includes a top plate including a dielectric material and an outer dielectric surface configured to support a substrate, printed heater sealed within the top plate, and a printed electrostatic chuck (ESC) circuit sealed within the top plate. A printed wiring layer may also be sealed within the top plate. The printed heater includes a heater material printed on a first interior dielectric surface of the top plate. The printed ESC circuit includes an electrically conductive material printed on a second interior dielectric surface of the top plate. When included, the printed wiring layer may include wiring traces printed on a third interior dielectric surface of the top plate. A dielectric base layer with vias electrically coupling the wiring traces to the printed heater may be included between the printed wiring layer and the printed heater.

### TECHNICAL FIELD

The present invention relates generally to heated substrate supports, and, in particular embodiments, to systems and methods for using and fabricating substrate supports that have a printed heater.

### BACKGROUND

Microelectronic device fabrication typically involves a series of manufacturing techniques that include formation, patterning, and removal of a number of layers of material on a substrate (e.g., a wafer). The manufacturing techniques are used to form networks of electronic components and interconnect elements (e.g., transistors, resistors, capacitors, metal lines, contacts, and vias) integrated in a monolithic structure (i.e., an integrated circuit). Temperature control of the substrate is required at various stages of fabrication. For example, an elevated substrate temperature may be desirable during processes such as bakes, anneals, depositions, and etching, among others.

In order to increase the temperature of the substrate in a controlled manner, heaters are often included in the substrate support, such as in a vacuum chuck or an electrostatic chuck (ESC). The heaters may also be divided into heating zones to allow the temperature in different regions of the substrate to be adjusted. Heaters can be categorized by the material used for the heating element. One type of heater employs a metal heating stage (i.e., the heating elements are enclosed in a dielectric material, such as magnesium oxide (MgO) within a metal heating stage). Metal stage heater technology can reach high temperatures (greater than 300° C. and upwards of 750° C.). However, the number of possible heating zones is limited (e.g., to two) by MgO cable technology, which are bulky and prefabricated. Additionally, because the metal heating stage is metal, it is not possible to combine metal stage heater technology with ESC directly applied to its surface.

Another type of heater uses a ceramic heater stage. In comparison to metal stage heaters, ceramic stage heaters use heating elements that may be made thinner because no dielectric must be included between the heating element and the ceramic heating stage and also because ceramic stage heaters are manufactured using a different process (e.g., powder sintering rather than brazing). A ceramic stage heater is fabricated during a powder sintering process by beginning with a powdered material and applying pressure and high heat in a controlled atmosphere to chemically bond the powder to itself. It is intrinsically difficult to precisely control the dimensionality of the particles during the compaction and heating required for powder sintering. As a result, complex shapes with high tolerances are not possible with powder sintered ceramic stage heaters. Ceramic stage heater technology may be successfully fabricated with up to six zones, but there is a significant manufacturing cost. Further, achieving the required thermal and ESC uniformity pushes the limits of manufacturability.

Conventional heater technology is inflexible and expensive with long development cycles. Even small changes in the lengths of the heating elements can result in extensive equipment changes further lengthening the production cycle and increasing cost. Moreover, the demand for precise control over substrate temperature is increasing. Thick heaters with a small number of zones and low tolerances are incapable of providing the requisite temperature control. Therefore, improved heater technology is desirable.

### SUMMARY

In accordance with an embodiment of the invention, a substrate support includes a top plate including a dielectric material and an outer dielectric surface configured to support a substrate, printed heater sealed within the top plate, and a printed electrostatic chuck (ESC) circuit sealed within the top plate. The printed heater includes a heater material printed on a first interior dielectric surface of the top plate. The printed ESC circuit includes an electrically conductive material printed on a second interior dielectric surface of the top plate.

In accordance with another embodiment of the invention, a substrate support includes a top plate including a dielectric material and an outer dielectric surface configured to support a substrate, a printed heater sealed within the top plate, a printed wiring layer sealed within the top plate, and a dielectric base layer disposed between the printed wiring layer and the printed heater. The printed heater includes a heater material printed on a first interior dielectric surface of the top plate. The printed wiring layer includes wiring traces printed on a second interior dielectric surface of the top plate. The dielectric base layer including vias electrically coupling the wiring traces to the printed heater.

In accordance with still another embodiment of the invention, a method of fabricating a substrate support includes printing a heater material onto a dielectric base layer of the substrate support as thermal traces to form a printed heater, and sealing the printed heater within the substrate support by printing a dielectric top layer over the printed heater.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example substrate support that has a printed heater sealed within a top plate in accordance with embodiments of the invention;

FIG. 2 illustrates another example substrate support that has a printed heater sealed within a top plate where printed electrodes are also included and the top plate is formed using multiple dielectric layers and sealed with a dielectric top layer and a dielectric side layer in accordance with embodiments of the invention;

FIG. 3 illustrates example tolerances of thermal traces for a printed heater and electrical traces for other printed circuits contrasted with conventional tolerances in accordance with embodiments of the invention;

FIG. 4 illustrates a side view and a corresponding plan view of still another example substrate support that has a printed heater sealed within a top plate where the printed heater includes multiple printed heater zones electrically coupled to a printed wiring layer that is also sealed within the top plate in accordance with embodiments of the invention;

FIG. 5 illustrates a plan view of yet another example substrate support that has a printed heater sealed within a top plate wherein the printed heater includes a grid of multiple printed heater zones in accordance with embodiments of the invention;

FIG. 6 illustrates an example processing system that includes a processing apparatus having a processing chamber with a substrate support that has a printed heater sealed within a top plate in accordance with embodiments of the invention;

FIG. 7 illustrates an example method of fabricating a substrate support that has a printed heater sealed within a top plate in accordance with embodiments of the invention; and

FIG. 8 illustrates a side view and a corresponding plan view of a conventional heated support with a conventional metal heater for comparison with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Demands for increased control over the substrate temperature during processing continue to accelerate as structures become smaller, denser, and more complicated. For example, in the field of microelectronic device fabrication, such as semiconductor device fabrication, complex three-dimensional (3D) structures are stacked vertically with critical dimensions in the tens of nanometers (or even single digits). Independent control over the temperature in smaller and smaller regions of the substrate is desired. Additionally, because the margin for error is so small, temperature uniformity across the entire substrate (e.g., wafer) during processing is also increasing in importance. This is compounded by the desire to use larger wafers with larger numbers of dies to increase throughput.

Another result of the increased complexity of microelectronic device fabrication, is a desire to include additional functionality in substrate supports (e.g., wafer chucks). Some examples of enhanced functionality include multi-polar ESC electrodes to electrostatically clamp a substrate to the substrate support, multi-zone plasma electrodes to control electromagnetic parameters at the substrate (e.g., potential, electric field, magnetic field, etc., in the region of the substrate), fluid channels (e.g., for flowing liquid, gas, or both) for substrate cooling, vacuum chucking, back side purging, and others.

Conventional heated substrate supports struggle to meet these increasing demands. Many features, such as high numbers of zones or combinations of several functionalities in the same substrate support are simply not possible with conventional substrate support manufacturing techniques. Moreover, even when some of the desired functionality is achievable, the cost, complexity, and availability of conventionally manufacturing the substrate supports renders them impractical (e.g., because the substrate support must be manufactured as a single unified piece, costing tens to hundreds of thousands of dollars per substrate support, and rapidly increasing with increased functionality).

In accordance with embodiments herein described, the invention proposes systems and methods for using and fabricating substrate supports that have a printed heater. The substrate support includes a top plate (e.g., comprising a dielectric material) that is optionally supported by a metal base plate. A heater material is printed on an interior dielectric surface of the top plate (such as an exposed surface of a dielectric base layer) to form a printed heater. The printed heater is configured to controllably radiate heat when an electric current passes through thermal traces of the heater (i.e., through the process of Joule heating, also known as Ohmic heating due to the correlation between the resistance of the thermal traces and the supplied heat). The printed heater is sealed within the top plate (e.g., by forming a dielectric top layer over the printed heater during the fabrication process, such as by printing the dielectric top layer).

Any of the structures in the top plate including materials of the top plate itself, such as various dielectric materials, may be printed. The top plate may comprise multiple layers included other printed circuits and structures. For instance, each of the dielectric layers separating the multiple layers of printed circuits may themselves be printed. Other printed circuits may include ESC circuits, plasma electrodes (e.g., bias electrodes used to control electric potential at the substrate during plasma processing), wiring circuits, and others. For example, an electrically conductive material may be printed on an interior dielectric surface of the top plate, which may be the same surface as for the printed heater (i.e., they are in the same layer), or a different surface (i.e., they are in different layers) to form a printed electric circuit (such as a printed ESC circuit).

Various potential benefits may be achieved by the systems and methods for using and fabricating substrate supports that have a printed heater. Advantageously, printed structures, such as traces can be fabricated with significantly higher precision than conventional heater fabrication methods such as powder sintering, brazing, welding, casting, etc. For example, the printed traces (e.g., thermal traces, electrical traces, wiring traces, fluid channels, and others) may be much thinner). This may advantageously be true in both the lateral direction (such as between traces of the same layer) and the vertical direction (such as between traces of different layers).

This may have the benefit of enabling complex planar designs (e.g., much more dense structures, with tolerances on the order of 0.5 mm and lower) and 3D designs utilizing multiple stacked printed layers that are electrically connected with vias. The wiring may also be printed, which may be an advantage for fabricating complex wiring designs that avoid hot spots, may run anywhere in support substrate including to the edges of the substrate support, even outside the wafer area (as opposed to conventional wiring which is thick and constrained to the middle of the substrate support), and that may be in the top plate (e.g., one or more printed wiring layers that are sealed together with the printed circuits in the multilayers of the top plate. And yet, even with the additional layers and complexity, the overall thickness of the top plate may advantageously be reduced relative to conventional heaters because of the greater precision (e.g., much smaller pitch) of the printed structures.

Another potential advantage of the systems and methods for using and fabricating substrate supports that have a printed heater is the ability to use many different materials in the same sealed top plate of a substrate support. For example, conventional heaters require a single material or a very select few different materials to be used for a given structure (e.g., a single ceramic material that may be sintered around pre-formed heating elements). In contrast, the printed structures of the top plate of the substrate supports described herein may choose any number of different materials for use in the same substrate support during the fabrication process, such as different dielectric materials for different layers within the top plate, different electrically conductive materials for heater materials of the printed heater, and different electrode materials for bias electrodes and ESC electrodes.

Additionally, the universe of materials that may be selected for use (i.e., for printing as structures in the top plate of a substrate support that has a printed heater) far exceed the possible materials for conventional processes such as sintering, metal joining (brazing, soldering, welding, etc.), metal casting, and the like. This may provide myriad advantages for tuning the materials of individual structures and layers to fit a particular application or perform a desired function. For example, the material of the printed circuits may be individually tuned for the desired temperature range, the printed electrical circuits may be tuned to me more electrically or thermally conductive, intermediate layers or stacks of intermediate layers may be included between layers to compensate for differences in coefficients of thermal expansion (CTE), such as between ductile materials (e.g., metals) and brittle materials (e.g., ceramics). This may also result in a thinner overall structure since each material may be chosen to efficiently account for various strain considerations such as CTE (in contrast to increasing the thickness of the layers to increase mechanical stability).

The substrate supports that have a printed heater may advantageously use less material, which may make them smaller and/or cheaper. The increased control over fabrication and composition of the printed structures may result in increased reliability and improved performance attributes such as thermal accuracy, uniformity, efficiency, improved ramp rate, and others. The fully sealed nature of the top plate may also beneficially avoid problems associated with imperfect electrical connections and exposure within the vacuum of a processing chamber, such as arcing, corrosion, etc.

Further possible advantages include faster (and affordable) prototyping, variations in pattern complexity at different regions of wafer, and increased manufacturing control (from printing layers rather than sintering everything together at once and hoping everything aligns). The layer-by-layer nature of the printed structures also may advantageously increase manufacturing yield of the substrate support. For example, circuits and structures may be tested or characterized (e.g., electrically testing) at any desired layer during the fabrication process to make sure it works. In some case, the problems may be remedied (e.g., by removing and reforming a layer, modifying a layer, or adapting future layers to compensate for imperfections in a current layer).

Various features of the methods for fabricating substrate supports that have a printed heater may advantageously facilitate highly structurally and functionally complex substrate supports. For example, the high pitch, small tolerances, flexible choice of materials, and high accuracy of printing techniques may enable printed heaters with a large number of independently-controllable zones (e.g., much larger than conventional heater technology, such as hundreds or even thousands of heater zones, each with one or more heating elements separate from those of other zones, compared to at most six zones of conventional sintered heater technology).

Additionally, multiple types of printed circuits may be combined, such as printed multi-polar ESC circuits, printed multi-zone plasma electrodes (also with high numbers of zones, if desired), printed fluid channels for gas or liquid, printed wiring layers, and printed vias allowing 3D multilayer designs.

Conventional heaters are a single large piece that cannot be modified and must be replaced when the conventional heater becomes nonfunctional (whether because something goes wrong or through normal wear and tear). For this reason, conventional heaters may be very expensive. In comparison, implementations of the substrate support that has a printed heater that use a base plate (e.g., a metal base plate) may only require the top plate to be replaced or repaired (e.g., the base plate may be re-used) in the event that the substrate support malfunctions or reaches the end of its usefulness. The top plate may use less material and be less expensive to manufacture, which may beneficially lower maintenance costs of the substrate support.

Further advantages may exist for the methods of fabricating substrate supports that have a printed heater related to the printing equipment and printing process. For example, conventional sintering equipment is large, (e.g., having furnaces up to two stories tall, taking up whole rooms), consumes massive amounts of power (e.g., 500 kW, potentially needing special permits and dedicated power grid installations), and generates large amounts of heat (e.g., thousands of degrees, such as 2000° C.) which heats up the entire conventional heater, requiring all devices and structures involved to have an extremely high thermal budget. In comparison printing equipment used to fabricate the substrate supports that have a printed heater described herein may be much smaller (e.g., comparable to the size of the substrate support (or supports) being fabricated, generating less heat and only locally (e.g., at printing nozzles) and consuming less power (e.g., because the volume heated is far smaller, because the process is quicker, etc.).

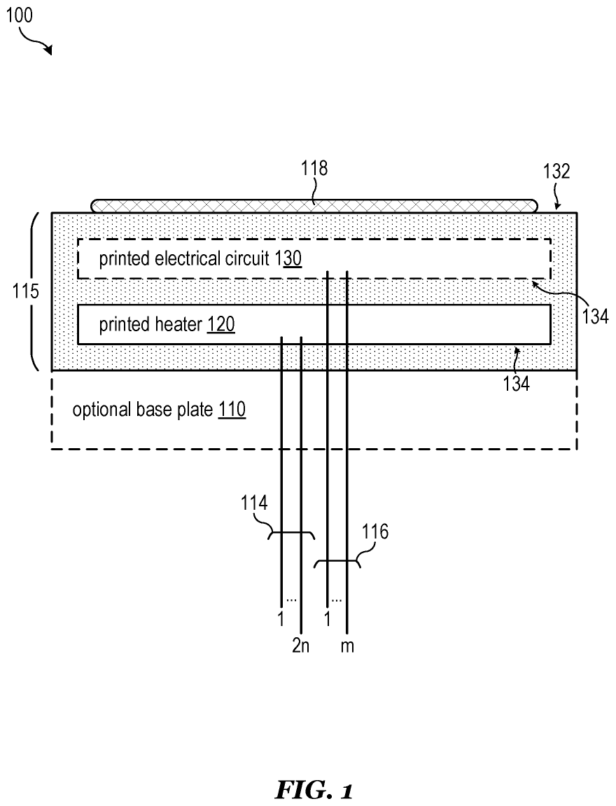

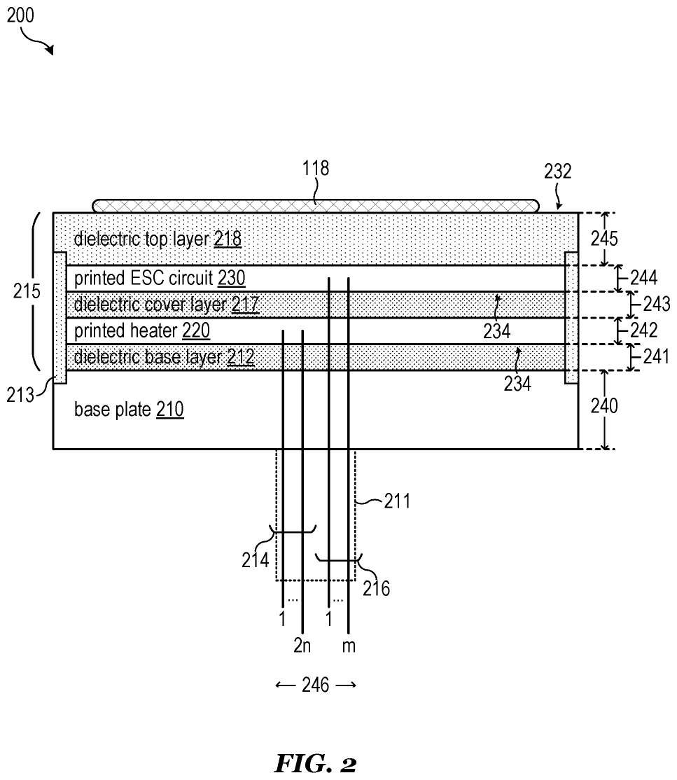

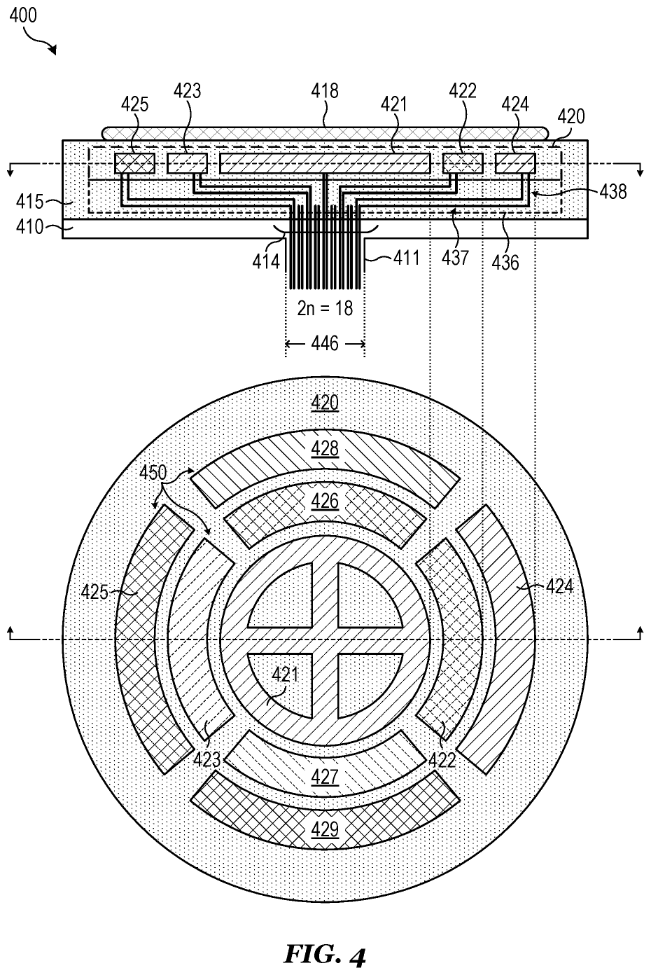

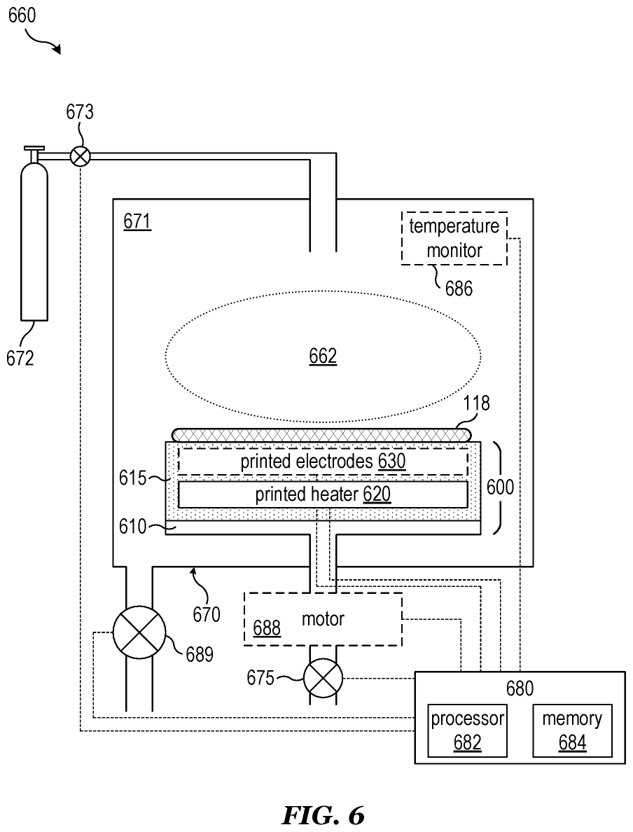

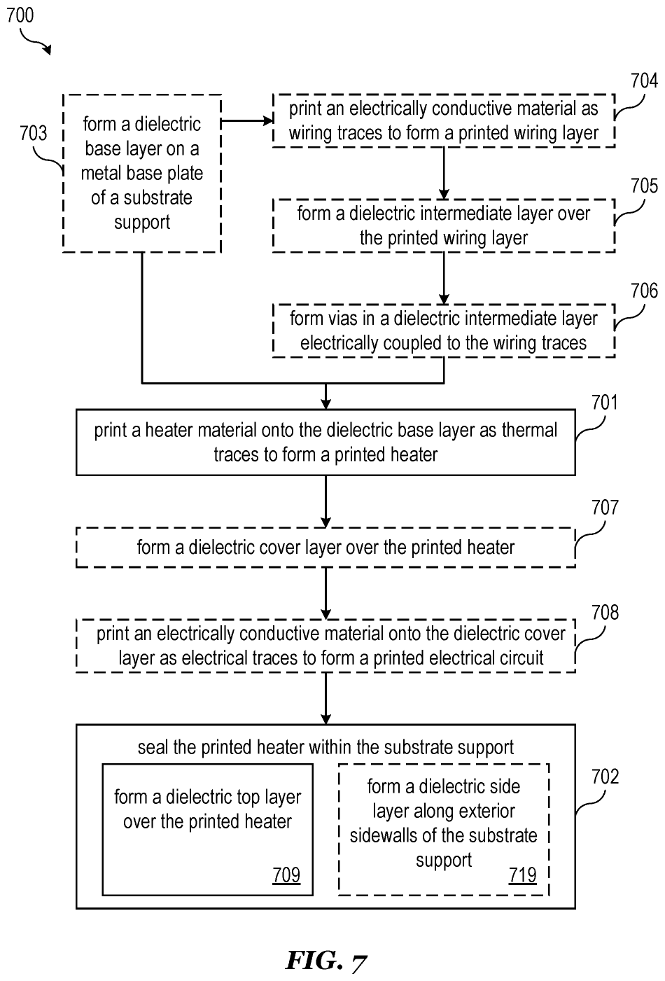

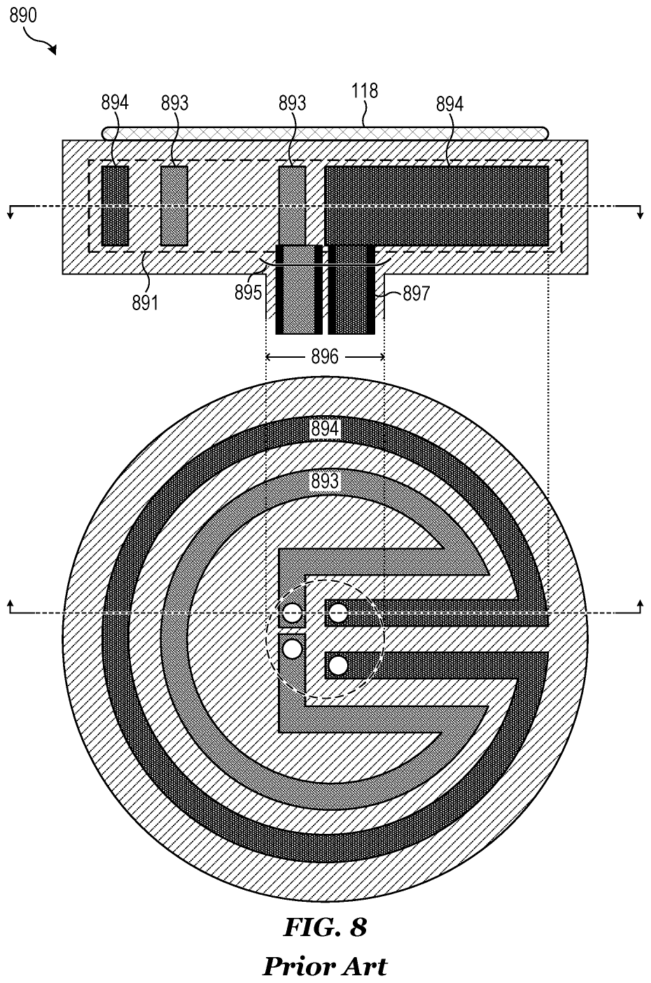

Embodiments provided below describe various systems and methods for using and fabricating heated substrate supports, and in particular embodiments, to substrate supports that have a printed heater. The following description describes the embodiments. FIG. 1 is used to describe an example substrate support. Another example substrate support is described using FIG. 2. Example tolerances for printed traces in embodiment substrate supports are described using FIG. 2 and compared to conventional tolerances. An example substrate support that includes multiple printed heater zones is described using FIG. 4 and compared to conventional heated supports with conventional metal heaters using FIG. 8. An example processing system including a substrate support that has a printed heater is described using FIG. 6 and FIG. 7 is used to describe an example method of fabricating a substrate support that has a printed heater.

FIG. 1 illustrates an example substrate support that has a printed heater sealed within a top plate in accordance with embodiments of the invention. Referring to FIG. 1, a substrate support 100 includes a printed heater 120 sealed within a top plate 115. One or more additional printed circuits may also be included (i.e., sealed within) the top plate 115, such as an optional printed electrical circuit 130 (e.g., a printed ESC circuit, a printed plasma electrode circuit, etc.). The top plate 115 includes an outer surface 132 that is configured to support a substrate 118. The various printed circuits and structures included in the top plate 115 may be printed on interior dielectric surfaces 134 of the substrate support 100 (i.e., as the top plate 115 is fabricated). The top plate 115 may be supported by (e.g., formed on, printed on, or otherwise attached to) an optional base plate 110, which may be a metal base plate in various embodiments.

The substrate support 100 may be any type of structure configured to support a substrate (such as the substrate 118) or multiple substrates during any type of process where elevation of the substrate temperature above the ambient temperature (even, a very cold ambient temperature) is desired. In various embodiments, the substrate support 100 is a single wafer chuck, such as an ESC chuck or a vacuum chuck. In one embodiment, the substrate support 100 is a multi-polar ESC chuck. It is also possible that the substrate support 100 does not have any additional retention mechanisms other than the outer surface 132, or only physical retention mechanisms, such as a recess or clips. Although the substrate support 100 is shown as being configured to support a single substrate (e.g., a wafer), this is not a requirement. The fabrication methods and structures of the substrate support 100 and other substrate supports described herein apply to any application where heat is needed, including track tools, multi-wafer supports, and others.

The substrate 118 may be any suitable substrate, such as an insulating, conducting, or semiconducting substrate with or without additional material layers disposed thereon. For example, the substrate 118 may be a semiconductor wafer, such as a silicon wafer, and include various layers, structures, and devices (e.g., forming integrated circuits). However, the substrate 118 may also be a metal substrate or a dielectric substrate, such as a glass substrate. In one embodiment, the substrate 118 includes silicon. In another embodiment, the substrate 118 includes silicon germanium (SiGe). In still another embodiment, the substrate 118 includes gallium arsenide (GaAs). Of course, many other materials, semiconductor or otherwise, may be included in the substrate 118 as may be apparent to those of skill in the art.

Electrical connections may be made to the printed heater 120 and the optional printed electrical circuit 130 using heater wires 114 and electrode wires 116 respectively. For example, when the printed heater 120 has multiple zones having a total of n heating elements, the number of heater wires 114 may be 2n in order to pass a current through each heating element. In contrast, when the optional printed electrical circuit 130 has m electrodes, the number of electrode wires 116 may be m (e.g., because a time-varying electric potential is being applying to each electrode and no return wire is used). Of course, this is merely provided as a simplified example to illustrate the concept, as the exact number and arrangement of wires will depend on the exact configuration of heating elements, electrodes, and any other components included in the top plate 115. Some or all of the heater wires 114 and the electrode wires 116 that are in the top plate 115 may be wire traces printed on interior dielectric surfaces 134 as part of one or more printed wiring layers that are sealed within the top plate 115.

Although illustrated as centrally located and extending directly vertically to the respective printed structures, the heater wires 114 and the electrode wires 116 may be routed in any configuration. Indeed, many possible benefits may be realized by routing the heater wires 114 and the electrode wires 116 towards edges of the substrate support 100 prior to vertically connecting the wires to the printed heater 120, the optional printed electrical circuit 130, and any other included printed circuits. Vertical electrical connections between layers within the top plate 115 may be accomplished using vias, which may be implemented in any suitable way, but are printed vias in various embodiments.

The top plate 115 includes a dielectric material (e.g., a material that is electrically insulating, at least in the context of the other components configured to function as electrically conducting within the top plate 115). Some example dielectric materials include oxides, nitrides, oxynitrides, and others. Many dielectric materials are considered to be ceramic materials (e.g., a nonmetallic solid material including at least two elements primarily held together with ionic or covalent bonds). Ceramic materials may include metal atoms, nonmetal atoms, or metalloid atoms. Ceramic materials are often considered to be inorganic, excluding hydrocarbons (e.g., hydrocarbon polymers), polyimide, and other materials recognized to be organic, but including some carbon-containing materials, such as silicon carbide. Other examples of ceramic materials include aluminum nitride, aluminum oxide, silicon nitride, silicon oxide, and beryllium oxide. Any combination of these dielectric materials may be included in the top plate 115, such as by printing dielectric layers (e.g., 3D printing ceramic materials).

The printed heater 120 is configured to elevate some or all regions of the substrate 118 to a temperature above the ambient temperature (i.e., by transferring heat to the substrate 118). The printed heater 120 includes a heater material (e.g., a material that more electrically-conductive than the dielectric material of the top plate 115) arranged in a configuration that provides the resistance necessary to generate the desired amount of heat when an electric current flows through the heater material. For example, the heater material may be a material that has higher resistivity or be arranged in a more resistive geometry (such as with reduced cross-sectional area and/or increased length) in order to increase the resistance of the heating elements formed from the printed heater material. In various embodiments, the heater material is a metal (such as nichrome, copper, tungsten, etc.). In other embodiments, the heater material is a ceramic material (such as aluminum nitride, silicon carbide, molybdenum silicide, etc.).

When included, the optional printed electrical circuit 130 may include an electrically conductive material (e.g., a material that is sufficiently electrically conductive so as to allow a substantially uniform electric potential to be applied to the electrode surfaces without generating undesirable heat). In some cases, the electrically conductive material of the optional printed electrical circuit 130 may be more electrically conductive than the heater material of the printed heater 120, but this is not required (such as if the desired resistance is obtained using a geometric configuration of a relatively electrically conductive material. Similarly, printed wiring traces may be a material with high electrical conductivity (which may advantageously provide the desired electrical connections with thin wires that do not generate much heat).

In some embodiments, the optional base plate 110 (or at least an upper surface of the optional base plate 110 may be formed from a “soft” metal, which may facilitate an interface between the top plate 115 and the optional base plate 110 that is resistant to fracturing or delaminating as a result of changes in temperature). Some examples of soft metals include so-called red metals (e.g., copper and copper alloys like brass and bronze), noble metals like gold, silver, and platinum, as well as corrosion resistant metals like aluminum, and others. Some examples of metals that may be used for the optional base plate 110 include stainless steel, (e.g., SS316), nickel alloys (for example, those that can provide enough stiffness at high temperatures) and similar alloys that are corrosion resistant. Also, aluminum alloy base plates may be used up to temperatures of about 350° C. and may be applicable for lower temperature printed heaters, such as those that include a printed ESC circuit. In some applications, a lower CTE metal base plate may be used. Of course, in the implementations where the bulk of the optional base plate 110 is a hard metal (e.g., stainless steel) and an upper surface is a soft metal, the soft metal and intervening layers (e.g., included for thermal expansion considerations, as adhesion layers, etc.) may be printed.

FIG. 2 illustrates another example substrate support that has a printed heater sealed within a top plate where printed electrodes are also included and the top plate is formed using multiple dielectric layers and sealed with a dielectric top layer and a dielectric side layer in accordance with embodiments of the invention. The substrate support of FIG. 2 may be a specific implementation of other substrate supports described herein such as the substrate support of FIG. 1, for example. Similarly labeled elements may be as previously described.

Referring to FIG. 2, a substrate support 200 includes a printed heater 220 sealed within a top plate 215. It should be noted that here and in the following a convention has been adopted for brevity and clarity wherein elements adhering to the pattern [x20] where ‘x’ is the figure number may be related implementations of a printed heater in various embodiments. For example, the printed heater 220 may be similar to the printed heater 120 except as otherwise stated. An analogous convention has also been adopted for other elements as made clear by the use of similar terms in conjunction with the aforementioned numbering system.

In this specific example, the top plate 215 is formed from multiple dielectric layers supported by a base plate 210 (e.g., a metal base plate). A printed heater 220 and a printed ESC circuit 230 (i.e., a specific implementation of a printed electrical circuit) are printed as separate layers on interior dielectric surfaces 134. For example, a dielectric base layer 212 is formed (e.g., by printing a dielectric material such as a ceramic material) on the base plate 210. Heater material is then printed on the exposed dielectric surface of the dielectric base layer 212 to form the printed heater 220. Although in some cases, heater circuits and electrical circuits may coexist in the same layer, a dielectric cover layer 217 is then formed (e.g., printed) over the printed heater 220.

An electrically-conductive material (which may be the same material as the heater material or a different material) is then printed on the exposed dielectric surface of the dielectric cover layer 217. The top plate 215 is then sealed by forming (e.g., printing) a dielectric top layer 218 over the printed ESC circuit 230. In some cases, the edges of the intermediate layers of the top plate 215 may require additional sealing to prevent exposure of the internal components of the substrate support 200 to the vacuum environment at the interface between layers. As shown in this specific example, a dielectric side layer 213 may be formed (e.g., printed, conformally deposited, etc.) on exterior sidewalls of the substrate support 200.

The dielectric side layer 213 is formed from a dielectric material that may be the same or different from the other dielectric materials of the top plate 215. As shown, the dielectric side layer 213 may overlap layers on either side of interfaces that are being sealed by the dielectric side layer 213. The size of the overlapping regions may be any size, for example, the dielectric side layer 213 may extend all the way to an outer surface 232 of the top plate 215 that is configured to support the substrate 118. The dielectric side layer 213 may or may not overlap the base plate 210.

Further, no substantial overlap may exist in certain implementations, such as when the dielectric side layer 213 is printed, whether as a part of the printing process of each layer to form a substantially planar complete layer before beginning the next layer, using a multi-axis printed process after forming the dielectric top layer 218, or by leaving space for the dielectric side layer 213 at the edge of the base plate 210 from the beginning and then printing the dielectric side layer 213 up from the base plate 210 to the upper surface of the printed ESC circuit 230 before printing or depositing the dielectric top layer 218. Of course, many other options may be apparent to those skilled in the art in view of this disclosure as flexibility in forming 3D structures with precision is an advantage of the printing process itself.

An optional base shaft 211 may be attached to or integrally formed with the base plate 210. The printed heater 220 and the printed ESC circuit 230 may be electrically coupled to external power and control using heater wires 214 and electrode wires 216, which may be routed through the optional base shaft 211, when included. The optional base shaft 211 has a shaft width 246, which may be at least partially dependent on the number and size of the heater wires 214 and the electrode wires 216, a potential advantage of the wiring of the substrate support 200 over conventional heated supports being the reduced size of the wires resulting the shaft width 246 being smaller than conventional shafts and/or containing far more wires (e.g., supporting higher numbers of zones, multiple circuits with additional functionality, etc.).

It should be noted, that here, as before, the routing of the heater wires 214 and the electrode wires 216 are shown conceptually to extend vertically straight to their respective printed circuits. Although this is on option, the top plate 215 and/or the base plate 210 may also include one or more wiring layers (e.g., formed in the base plate 210 and electrically connected to vias printed or formed in layers of the top plate 215 or printed as printed wiring layer(s) during the fabrication of the top plate 215). Advantages may be gained from locating wires in the top plate 215 and/or the base plate 210. For example, distributing the wiring throughout the lateral extent of the substrate support 200 may prevent hot spots, interferences, and enable more complicated circuits (e.g., zone shapes, locations, etc.). Including wiring in the base plate 210 may be advantageous to save costs when the base plate 210 is reusable and the top plate 215 must be repeatedly replaced. Including wiring in the top plate 215 may have benefits such as enhanced precision, control, and/or testing during manufacturing and also being sealed within the top plate 215.

The thickness of each of the layers included in the top plate 215 may be selected to accomplish a desired function or specification and may depend on the specific details of a given application. In general, a potential advantage of printing one or more of the layers of the top plate 215 is the ability to form thin layers out of any desired material, which allows the substrate support 200 to be both thinner than conventional heated supports while also including more functionality than conventional heated supports.

In various embodiments, the base plate thickness 240 may be greater than the top plate 215 (although not illustrated as such here). For example, the base plate thickness 240 may be on the order of one to tens of millimeters, such as in the range of about 5 mm to about 10 mm. In contrast, the total thickness of the entire top plate 215 (including base layer thickness 241, heater thickness 242, cover layer thickness 243, electrode thickness 244, and top layer thickness 245) may be less than 5 mm, such as in the range of about 0.5 mm to about 5 mm.

The relative thickness of the layers within the top plate 215 may vary widely based on the materials involved, the desired temperature range of the printed heater 220, the currents and voltages of the various circuits, and the specific desired capabilities of the substrate support 200. The printing techniques may advantageously enable very thin layers, such as less than about 0.5 mm, down to about 0.1 mm, and even lower. An example consideration is the even dispersion of heat (the cover layer thickness 243 may be thicker than the base layer thickness 241 to evenly disperse heat before reaching the substrate 118). Additionally, the thickness of dielectric layers (as well as the materials used) may be tuned to maintain electrical isolation between layers (e.g., between printed circuit layers, the printed heater, the base plate, the substrate, etc.).

Managing different CTEs between layers may also impact the thicknesses of various layers of the substrate support 200. Additionally, multiple layers may be included to mitigate the effects of thermal expansion on the structural integrity of the substrate support 200, which has been noted as potential advantage of the methods of fabricating substrate supports that have a printed heater described herein.

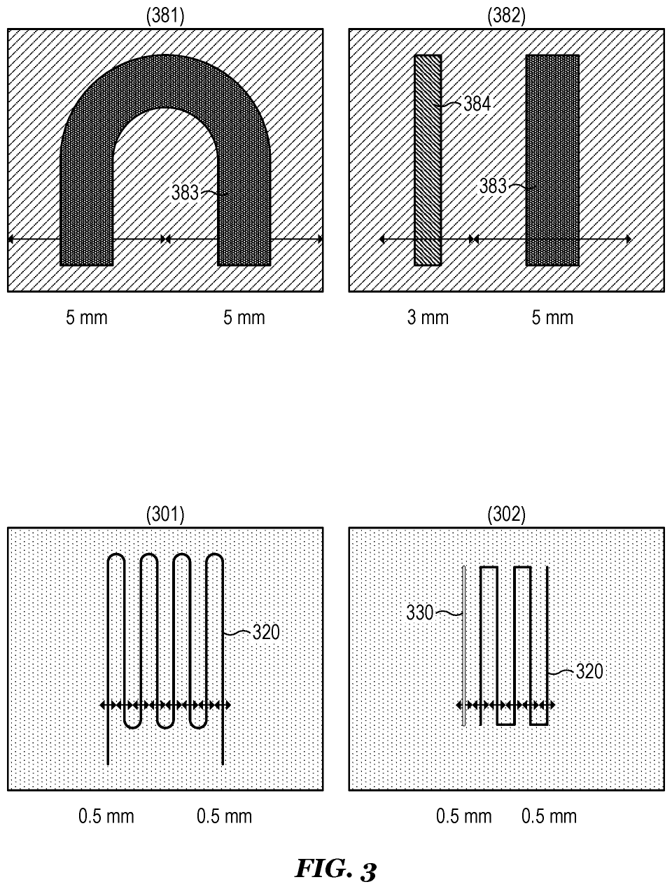

FIG. 3 illustrates example tolerances of thermal traces for a printed heater and electrical traces for other printed circuits contrasted with conventional tolerances in accordance with embodiments of the invention. The example tolerances of FIG. 3 may correspond with tolerances of printed traces of any of the substrate supports described herein such as the substrate support of FIG. 1, for example. Similarly labeled elements may be as previously described.

Referring to FIG. 3, two example scenarios are provided to demonstrate some differences between the tolerances of conventional heaters (shown as conventional heater tolerance 381 and conventional inter-grid tolerance 382) and the tolerances of printed heaters (shown as printed heater tolerance 301 and printed inter-grid tolerance 302). Specifically, the tolerances of conventional heaters (such as powder sintered ceramic heaters) are much larger. For example, the tolerance of thermal traces of a conventional sintered heater 383 are 5 mm (or higher) whereas the tolerance of electrical traces of a conventional sintered electrode 384 are still 3 mm (or higher).

The large tolerances of conventional sintered heaters are due to the unpredictability of the sintering process which simultaneously applies pressure and heat to a powdered material until the powder fuses into a monolithic structure. When the heat and pressure are applied, the exact effect on the shape of the material can only be determined for shapes dimensions larger than the tolerances.

On the other hand, the tolerances of printed heaters may be much smaller (such as by a factor of about 10 or more, as shown). In various embodiments, the tolerance of thermal traces of the printed heater 320 are less than 5 mm, and the tolerance of the thermal traces is about 0.5 mm in one embodiment (but may be even lower). Since the tolerance represents a dimension larger than the thermal trace itself (i.e., the thermal traces are not allowed to touch one another, and must maintain a certain distance on either side of the trace, which defines the tolerance, or the effective width of the thermal trace in a pattern), the thickness of the printed thermal traces of the printed heater 320 may be thinner than 0.5 mm, such as in the range of about 0.1 mm to about 0.5 mm, and is about 0.1 mm in one embodiment. Similarly, the tolerance of the printed electrical traces of a printed electrode 330 (or a wiring layer, etc.) are less than three millimeters (the lower limit of conventional heaters) in various embodiments and are about 0.5 mm in one embodiment (with the electrical traces having a similar, but not necessarily identical, thickness as the thermal traces of in the range of about 0.1 mm to about 0.5 mm).

Of course, while the primary factor influencing the tolerances of the printed structures is the fabrication of the structures using a printing process, the tolerances may also be affected by other factors, such as the type of material, shape of the structure, etc. Therefore, while the tolerances of printed traces are much lower than conventional traces, in some cases the printed heater tolerance 301 and the printed inter-grid tolerance 302 (and tolerances of other printed structures discussed herein, but not shown here) may be different from one another.

While many comparisons between conventional heated supports and the embodiment substrate supports described herein have already been discussed, FIG. 8 illustrates a side view and a corresponding plan view of a conventional heated support with a conventional metal heater and is provided for comparison with embodiments of the invention.

Referring to FIG. 8, a conventional heated support 890 includes a conventional metal heater 891 that is divided into two zones using an interior heating element 893 and an exterior heating element 894. Electrical connections to the conventional metal heater 891 are facilitated using conventional heater wires 895 (e.g., nichrome) that are electrically insulated from the body (e.g., brazed metal, sintered ceramic) of the conventional heated support 890 by conventional thick insulation 897 (e.g., MgO). The conventional heater wires 895 pass through a shaft portion of the conventional heated support 890 that has a conventional shaft width 896, which is made thick by the conventional thick insulation 897 (and only contains four wires that leave no room for anything else).

FIG. 4 illustrates a side view and a corresponding plan view of still another example substrate support that has a printed heater sealed within a top plate where the printed heater includes multiple printed heater zones electrically coupled to a printed wiring layer that is also sealed within the top plate in accordance with embodiments of the invention. The substrate support of FIG. 4 may be a specific implementation of other substrate supports described herein such as the substrate support of FIG. 1, for example. Similarly labeled elements may be as previously described.

Referring to FIG. 4, a substrate support 400 includes a printed heater 420 that has multiple printed heater zones sealed within a top plate 415 supported by a base plate 410. Although any desired number and configuration of zones is possible, in this specific example, the printed heater 420 is divided into nine heater zones, each having a separate heating element, including a center heating element 421, a right interior heating element 422, a left interior heating element 423, an upper interior heating element 426, a lower interior heating element 427, a right edge heating element 424, a left edge heating element 425, an upper edge heating element 428, and a lower edge heating element 429 (compared to the two heater zones of the conventional heated support 890).

Electrical connections are made to the zones of the printed heater 420 using heater wires 414 that are routed through a base shaft 411. In comparison to the four conventional heater wires 895 of the conventional heated support 890, the substrate support 400 has eighteen (2 for each zone) heater wires 414 running through the base shaft 411. Despite the increased number of wires, the shaft width 446 may be made thinner than the conventional shaft width 896 by virtue of the heater wires 414 in the shaft not having to endure harsh manufacturing conditions such as brazing or sintering.

Additionally, the heater wires 414 are distributed away from the center of the substrate support 400 using a wiring layer 436 (which may also be included instead in the base plate 410). In various embodiments, the wiring layer 436 includes printed wiring traces 437 and vias 438. The printed wiring traces 437 may enjoy any of the aforementioned advantages of other printed structures, including small and precise dimensionality, flexibility in material choice, complexity of design, and per-layer testing capabilities, among others. The vias 438 may be formed by any suitable means, including printing.

The wiring layer 436 is illustrated conceptually and may be multilayer or planar in various embodiments. Further, although the specific example of substrate support 400 shows only a printed heater 420, one or more additional printed circuits (e.g., printed multi-polar ESC circuits, printed multi-zone plasma electrodes (also with high numbers of zones, if desired), printed fluid channels for gas or liquid, and others) may be included. For this reason, multiple wiring layers may be included in the wiring layer 436 (or between other layers in the vertical structure of the top plate 415. Alternatively, all the printed wiring traces 437 (even for many more zones and printed circuits) may be printed in a single planar wiring layer, which may be enabled by the small dimensionality of the printed wiring traces 437.

Another potential advantage of using the wiring layer 436 with the printed wiring traces 437 is that the vias 438 may be fabricated outside the boundary of the substrate 118. That is, the various zones of printed circuits such as the printed heater 420 may be vertically aligned with the substrate 118 in order to achieve the desired influence on regions of the substrate 118 (e.g., thermal, electrical, magnetic, etc.) whereas the vias 438 may not vertically align with the substrate 118. This may have many benefits, one of which may be to avoid hot spots on the substrate 118 during substrate processing. For example, a hot spot may be any undesirable localized effect that is caused by the spatial orientation of the electric circuitry (such as the printed wiring traces 437).

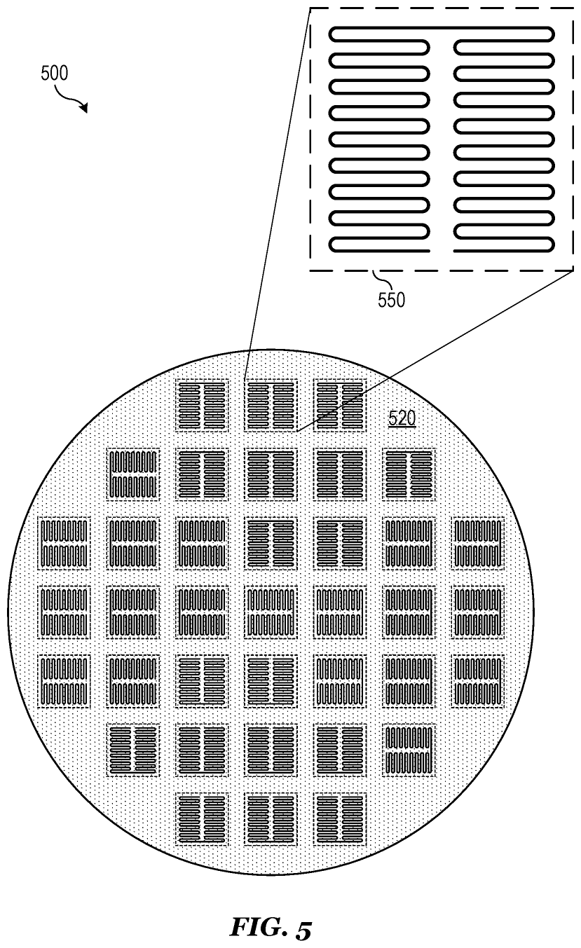

FIG. 5 illustrates a plan view of yet another example substrate support that has a printed heater sealed within a top plate wherein the printed heater includes a grid of multiple printed heater zones in accordance with embodiments of the invention. The substrate support of FIG. 5 may be a specific implementation of other substrate supports described herein such as the substrate support of FIG. 1, for example. Similarly labeled elements may be as previously described.

Referring to FIG. 5, a substrate support 500 includes a printed heater 520 with multiple printed heater zones 550. For example, the substrate support 500 may be similar to the substrate support 400 except that there are more printed heater zones 550 (e.g., independently-controllable zones that each include one or more printed heating elements that are separate from heating elements of other printed heater zones) arranged in a grid (of course, any desired configuration and number are possible). For example, in various embodiments, the printed heater 520 may include tens of printed heater zones 550 (as shown) and may include far more, if desired. In one embodiment, the printed heater 520 includes a printed heater zone for each die of a substrate being processed while supported by the substrate support 500. As a result, such a printed heater 520 may include hundreds of printed heater zones 550 (e.g., around 300, but of course any number is possible). For example, the printed heater 520 may include hundreds or even thousands of printed heater zones, only limited by the tolerances (e.g., less than 0.5 mm or even lower).

FIG. 6 illustrates an example processing system that includes a processing apparatus having a processing chamber with a substrate support that has a printed heater sealed within a top plate in accordance with embodiments of the invention. The substrate support in the processing system of FIG. 6 may correspond with any of the substrate supports described herein such as the substrate support of FIG. 1, for example. Similarly labeled elements may be as previously described.

Referring to FIG. 6, a processing system 660 (e.g., a deposition system, an etching system, or a multipurpose system, such as a chemical vapor deposition (CVD) system or a plasma etching system like a reactive-ion etching (RIE) etching system) includes a substrate support 600 disposed within a processing chamber 671 and configured to support a substrate 118. A processing gas source 672 (e.g., a gas source or sources including species configured to process the substrate 118) is fluidically coupled to the processing chamber 671 through a processing gas valve 673. Additional gas sources and valves may also be included in the processing system 660. An exhaust valve 689 is included to evacuate the processing chamber 671 during the processing of the substrate 118.

The processing system 660 may be configured to generate an optional plasma 662 during any or all of the steps of a process. The processing chamber 671 may be any suitable processing chamber, such as a CVD chamber, an atomic layer deposition (ALD) chamber, a molecular layer deposition (MLD) chamber, a capacitively couple plasma (CCP) etching chamber, an inductively coupled plasma (ICP) etching, chamber, etc. Of course, the processing chamber 671 may be configured to perform multiple processing steps in situ, such as deposition steps, etching steps, baking steps, cleaning steps, and others. Further, a processing system like the processing system 660 may be itself configured to fabricate the substrate support 600 in situ, such as using a base plate 610 (e.g., a metal base plate) as a substrate.

A printed heater 620 is included to elevate the temperature of the substrate 118 above the equilibrium temperature at the substrate 118 during processing. The printed heater 620 is sealed within a top plate 615 and may be supported by a base plate 610 (e.g., a metal base plate). Additionally, a cooler may also be included (e.g., a printed cooler with fluid channels being defined by printed channel walls) to decrease the temperature of the substrate 118 below equilibrium. Additional printed electrodes 630 may also be included (such as a printed ESC circuit, a printed plasma electrode circuit, printed wiring circuits, etc.).

An optional temperature monitor 686 may be included to monitor and/or aid in controlling the temperature of the substrate 118 and the environment in the processing chamber 671. For example, the optional temperature monitor 686 may be configured to monitor multiple regions of the substrate 118 so that various printed heater zones may be independently adjusted during processing. Temperature sensors may also be included in the substrate support 600 itself (e.g., fabricated using printed structures). An optional motor 688 may also be included to improve deposition uniformity.

A controller 680 is operationally coupled to the valves (the processing gas valve 673, and any other included source gas valves), and may be operationally coupled to any of the printed heater 620, the optional printed electrodes 630, the optional temperature monitor 686, the optional motor 688, and the exhaust valve 689. The controller 680 includes a processor 682 and a memory 684 (i.e., a non-transitory computer-readable medium) that stores a program including instructions that, when executed by the processor 682, perform substrate processing (such as structure formation, including even forming the substrate support 600 itself). For example, the memory 684 may have volatile memory (e.g., random access memory (RAM)) and non-volatile memory (e.g., flash memory). Alternatively, the program may be stored in physical memory at a remote location, such as in cloud storage. The processor 682 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 7 illustrates an example method of fabricating a substrate support that has a printed heater sealed within a top plate in accordance with embodiments of the invention. The method of FIG. 7 may be combined with other methods and performed using the systems and apparatuses as described herein. For example, the method of FIG. 7 may be combined with any of the embodiments of FIGS. 1-6. Although shown in a logical order, the arrangement and numbering of the steps of FIG. 7 are not intended to be limited. The method steps of FIG. 7 may be performed in any suitable order or concurrently with one another as may be apparent to a person of skill in the art.

Referring to FIG. 7, a method 700 of fabricating a substrate support that has a printed heater sealed within a top plate includes a printing step 701 during which a heater material (e.g., a metal such as nichrome, copper, tungsten, or a ceramic material such as aluminum nitride, silicon carbide, molybdenum silicide, etc.) is printed onto a dielectric base layer of the substrate support. For example, the heater material may be deposited as thermal traces with spatial precision (e.g., less than 0.5 mm) to form a printed heater on the dielectric base layer. Then, in a sealing step 702, the printed heater is sealed within the substrate support by forming (e.g., printing) a dielectric top layer (possible dielectrics including an oxide, nitride, oxynitride, etc., such as ceramic materials such as aluminum nitride, aluminum oxide, silicon oxide, beryllium oxide, and others) over the printed heater (top layer formation step 709). Optionally, the sides of the various printed layers may also need to be sealed. In this case, an optional sidewall formation step 719 may be included in the sealing step 702 during which a dielectric side layer is formed (e.g., printed) on exterior sidewalls of the substrate support.

In various embodiments, the dielectric base layer may be formed before the printing step 701 in an optional base layer formation step 703. For example, the method 700 may include forming (e.g., printing) the dielectric base layer on a base plate (e.g., a metal base plate) of the substrate support. Additionally, the method 700 may have the advantage of taking place entirely in situ in a controlled (e.g., clean vacuum) environment, such as in a processing chamber. That is, at the beginning of the process, the initial substrate (a dielectric substrate or a base plate) may be placed in the processing chamber and the entire fabrication process may take place in situ to avoid contamination or disruption resulting in a sealed top plate that is protected from the external environment before being removed from the processing chamber. In some cases, all structures beginning with the dielectric base layer and ending with a dielectric top layer (and optionally dielectric sidewalls) may be printed, which may advantageously facilitate in situ processing in a single chamber, such as the processing chamber of a printing apparatus capable of printing dielectric (e.g., ceramic) materials.

Of course, many other intermediate steps may be included to form (e.g., print) other structures, circuits, and devices that are also sealed within the substrate support and contribute to desired functionality. One of the additional circuits that may be included in the substrate support is a printed wiring layer to provide electrical connectivity to the printed heater. For example, in an optional wiring trace printing step 704, wiring traces may be printed on a dielectric layer, such as the dielectric base layer, to form a printed wiring layer (e.g., the wiring traces may be distributed within the printed wiring layer from a central region of the substrate support to align with various locations of printed heater zones of the printed heater).

The wiring traces of the printed wiring layer and the thermal traces of the printed heater may be in different layers of the top plate (e.g., the printed wiring layer may be below the printed heater). To facilitate this, an intermediate dielectric layer may be formed (e.g., printed) over the printed wiring layer in an optional intermediate layer formation step 705. Then, in an optional via formation step 706, vias may be formed, which may also be printed) in the intermediate dielectric layer electrically coupled to the wiring traces. In this specific example, the intermediate dielectric layer would then serve as the dielectric base layer for the printing step 701 and various heating elements of the printed heater would be printed such that they were electrically coupled to the appropriate vias (e.g., to facilitate multiple independently-controllable heater zones, such as greater than six, or even on a per-die basis).

Another additional circuit that may be included in the substrate support is a printed electrical circuit (e.g., a printed ESC circuit, a printed plasma electrode circuit, or both). Similar to the layer-by-layer printing approach used when including both a printed wiring layer and a printed heater layer, dielectric layers may be formed and printed on to form the printed electrical circuit(s). For example, in an optional cover layer formation step 707, a dielectric cover layer may be formed (e.g., printed) over the printed heater. The dielectric cover layer may then serve as a base layer for printing an electrically conductive material as electrical traces (also with high spatial precision, such as less than 0.5 mm) to form a printed electrical circuit in an optional electrical printing step 708.

When one or more additional printed layers are included, the dielectric top layer is formed (e.g., printed) over all the layers in the top layer formation step 709. Additionally, via steps may be included in any of the layers to make electrical connections between upper layers and an underlying printed wiring layer. The dielectric materials formed over printed circuits may fill empty space in the underlying layer (may be conformal and smooth the surface into a substantially planar surface as more of the material is deposited or printed). This may allow vias extending through a dielectric layer to also make electrical contact with vias formed in a lower dielectric layer (e.g., through an intervening printed layer, such as the printed heater). However, even if this is not the case, vias may be formed in a layer containing printed structures in order to provide the desired vertical electrical connectivity.

Example embodiments of the invention are summarized here. Other embodiments can also be understood from the entirety of the specification as well as the claims filed herein.

Example 1. A substrate support including: a top plate including a dielectric material and an outer dielectric surface configured to support a substrate; a printed heater sealed within the top plate, the printed heater including a heater material printed on a first interior dielectric surface of the top plate; and a printed electrostatic chuck (ESC) circuit sealed within the top plate, the printed ESC circuit including an electrically conductive material printed on a second interior dielectric surface of the top plate.

Example 2. The substrate support of example 1, further including: a metal base plate supporting the top plate.

Example 3. The substrate support of one of examples 1 and 2, where the top plate includes a dielectric base layer, and where the first interior dielectric surface and the second dielectric interior surface are the same dielectric surface of the dielectric base layer.

Example 4. The substrate support of one of examples 1 and 2, where the top plate includes a dielectric base layer including the first interior dielectric surface, and a dielectric cover layer including the second interior dielectric surface.

Example 5. The substrate support of one of examples 1 to 4, where the heater material is a metallic material, and where the dielectric material is aluminum nitride.

Example 6. The substrate support of one of examples 1 to 5, further including: a printed wiring layer sealed within the top plate and including wiring traces electrically coupled to the printed heater, the wiring traces being printed on a third interior dielectric surface of the top plate.

Example 7. The substrate support of example 6, where the printed wiring layer is disposed below the printed heater, where the top plate includes a dielectric base layer including the first interior dielectric surface, and where the wiring traces are electrically coupled to the printed heater using vias extending through the dielectric base layer.

Example 8. A substrate support including: a top plate including a dielectric material and an outer dielectric surface configured to support a substrate; a printed heater sealed within the top plate, the printed heater including a heater material printed on a first interior dielectric surface of the top plate; a printed wiring layer sealed within the top plate and including wiring traces printed on a second interior dielectric surface of the top plate; and a dielectric base layer disposed between the printed wiring layer and the printed heater, the dielectric base layer including vias electrically coupling the wiring traces to the printed heater.

Example 9. The substrate support of example 8, further including: a metal base plate supporting the top plate.

Example 10. The substrate support of one of examples 8 and 9, where the printed heater is divided into a plurality of independently-controllable zones greater than six, each including a separate heating element.

Example 11. The substrate support of example 10, where each heater zone of the plurality of independently-controllable zones corresponds to each die of the substrate in a one-to-one ratio.

Example 12. The substrate support of one of examples 8 to 11, where thermal traces of the printed heater have a tolerance of less than five millimeters.

Example 13. The substrate support of example 12, where the thermal traces have a width less than 0.5 millimeters.

Example 14. The substrate support of one of examples 12 and 13, further including: a printed electrical circuit sealed within the top plate, the printed electrical circuit including electrical traces having a tolerance less than three millimeters.

Example 15. A method of fabricating a substrate support, the method including: printing a heater material onto a dielectric base layer of the substrate support as thermal traces to form a printed heater; and sealing the printed heater within the substrate support by printing a dielectric top layer over the printed heater.

Example 16. The method of example 15, further including: printing the dielectric base layer on a metal base plate of the substrate support.

Example 17. The method of one of examples 15 and 16, further including: printing a dielectric cover layer over the printed heater; printing an electrically conductive material onto the dielectric cover layer as electrical traces to form a printed electrostatic chuck (ESC) circuit; and where sealing the printed heater within the substrate support further includes printing the dielectric top layer over the printed ESC circuit.

Example 18. The method of one of examples 15 to 17, where printing the dielectric base layer, printing the heater material, and sealing the printed heater within the substrate support are all performed in situ within a single processing chamber.

Example 19. The method of one of examples 15 to 18, further including: printing an electrically conductive material as wiring traces to form a printed wiring layer below the printed heater; forming vias in the dielectric base layer electrically coupled to the wiring traces before printing the heater material; and where the printed heater includes a plurality of independently-controllable heater zones electrically coupled to the vias.

Example 20. The method of one of examples 15 to 19, where sealing the printed heater within the substrate support further includes forming a dielectric side layer on exterior sidewalls of the substrate support.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A substrate support comprising:
a top plate comprising a dielectric material and an outer dielectric surface configured to support a substrate;
a printed heater sealed within the top plate, the printed heater comprising a heater material printed on a first interior dielectric surface of the top plate; and
a printed electrostatic chuck (ESC) circuit sealed within the top plate, the printed ESC circuit comprising an electrically conductive material printed on a second interior dielectric surface of the top plate.

2. The substrate support of claim 1, further comprising:
a metal base plate supporting the top plate.

3. The substrate support of claim 1, wherein the top plate comprises a dielectric base layer, and wherein the first interior dielectric surface and the second dielectric interior surface are the same dielectric surface of the dielectric base layer.

4. The substrate support of claim 1, wherein the top plate comprises a dielectric base layer comprising the first interior dielectric surface, and a dielectric cover layer comprising the second interior dielectric surface.

5. The substrate support of claim 1, wherein the heater material is a metallic material, and wherein the dielectric material is aluminum nitride.

6. The substrate support of claim 1, further comprising:
a printed wiring layer sealed within the top plate and comprising wiring traces electrically coupled to the printed heater, the wiring traces being printed on a third interior dielectric surface of the top plate.

7. The substrate support of claim 6, wherein the printed wiring layer is disposed below the printed heater, wherein the top plate comprises a dielectric base layer comprising the first interior dielectric surface, and wherein the wiring traces are electrically coupled to the printed heater using vias extending through the dielectric base layer.

8. A substrate support comprising:
a top plate comprising a dielectric material and an outer dielectric surface configured to support a substrate;
a printed heater sealed within the top plate, the printed heater comprising a heater material printed on a first interior dielectric surface of the top plate;
a printed wiring layer sealed within the top plate and comprising wiring traces printed on a second interior dielectric surface of the top plate; and
a dielectric base layer disposed between the printed wiring layer and the printed heater, the dielectric base layer comprising vias electrically coupling the wiring traces to the printed heater.

9. The substrate support of claim 8, further comprising:
a metal base plate supporting the top plate.

10. The substrate support of claim 8, wherein the printed heater is divided into a plurality of independently-controllable zones greater than six, each comprising a separate heating element.

11. The substrate support of claim 10, wherein each heater zone of the plurality of independently-controllable zones corresponds to each die of the substrate in a one-to-one ratio.

12. The substrate support of claim 8, wherein thermal traces of the printed heater have a tolerance of less than five millimeters.

13. The substrate support of claim 12, wherein the thermal traces have a width less than 0.5 millimeters.

14. The substrate support of claim 12, further comprising:
a printed electrical circuit sealed within the top plate, the printed electrical circuit comprising electrical traces having a tolerance less than three millimeters.

15. A method of fabricating a substrate support, the method comprising:
printing a heater material onto a dielectric base layer of the substrate support as thermal traces to form a printed heater; and
sealing the printed heater within the substrate support by printing a dielectric top layer over the printed heater.

16. The method of claim 15, further comprising:
printing the dielectric base layer on a metal base plate of the substrate support.

17. The method of claim 15, further comprising:
printing a dielectric cover layer over the printed heater;
printing an electrically conductive material onto the dielectric cover layer as electrical traces to form a printed electrostatic chuck (ESC) circuit; and
wherein sealing the printed heater within the substrate support further comprises printing the dielectric top layer over the printed ESC circuit.

18. The method of claim 15, wherein printing the dielectric base layer, printing the heater material, and sealing the printed heater within the substrate support are all performed in situ within a single processing chamber.

19. The method of claim 15, further comprising:
printing an electrically conductive material as wiring traces to form a printed wiring layer below the printed heater;
forming vias in the dielectric base layer electrically coupled to the wiring traces before printing the heater material; and
wherein the printed heater comprises a plurality of independently-controllable heater zones electrically coupled to the vias.

20. The method of claim 15, wherein sealing the printed heater within the substrate support further comprises forming a dielectric side layer on exterior sidewalls of the substrate support.
